(19) United States
(12) Patent Application Publication
(10) Pub. No.: US 2025/0102546 A1
(43) Pub. Date: Mar. 27, 2025

(54) TIME ALIGNMENT OF SENSOR DATA

(71) Applicant: Meta Platforms Technologies, LLC, Menlo Park, CA (US)

(72) Inventor: Patrick Edward LANDREMAN-LAPORTE, Palo Alto, CA (US)

(21) Appl. No.: 17/827,187

(22) Filed: May 27, 2022

(51) Int. Cl. G01R 19/00; G01J 1/44

(52) U.S. Cl. CPC G01R 19/0084; G01J 1/44; G01J 2001/446

(57) ABSTRACT

Methods and corresponding systems and apparatuses for time-aligning a first set of measurement samples captured by a first sensor to a second set of measurement samples captured by a second sensor. Each sensor captures samples at regular intervals corresponding to a respective sampling period. The sensors directly or indirectly measure at least one reference signal. Each reference signal includes a reference marker followed by a sequence of alignment pulses. In the case of multiple reference signals, the sequence of alignment pulses can differ, but the reference marker can be identical. In some implementations, time-alignment involves assigning a timestamp to a first alignment pulse in the first set of measurement samples, relative to the reference marker in the first set of measurement samples and assigning a second timestamp to a second alignment pulse in the second set of measurement samples, relative to the reference marker in the second set of measurement samples.

### BACKGROUND

In a multi-sensor system, measurements by different sensors can be combined for processing. In some instances of combined processing, it is desirable to correlate measurements from one sensor with measurements from another sensor in order to determine the relative timing of events represented in the sensor data. A sensor's measurements are often generated according to a sampling frequency or sampling rate set by a local clock of the sensor. Determining the relative timing of measurements can be challenging due to sensors operating at different sampling frequencies. Further, even when sensors run at the same sampling frequency, the clocks of different sensors may be unsynchronized, making it difficult to determine when the measurements of one sensor occurred relative to the measurements of another sensor. This is especially true when the sensors are not collocated. When sensors are in different locations, the sensors may detect the same event (or contemporaneous events) at different times, for example, due to propagation delay of the physical phenomenon being measured.

Additionally, the accuracy with which a timestamp can be assigned to a sample is limited by the duration of a sampling period corresponding to the length of time between consecutive samples. Because an event represented by a sample, e.g., as a change in voltage, may not always coincide with a sampling time, there is inherent uncertainty as to the exact instant at which the event occurred. This uncertainty can be problematic when the event, or some inter-sensor temporal relationship of interest, occurs on a time scale that is smaller than the sampling period of the sensor. For example, if the sampling period is 10 milliseconds (ms) long and the event is 2 ms long, it is not possible to know, absent additional information, whether the event occurred exactly at the time the current sample was captured or sometime during the 10 ms interval between the previous sample and the current sample. For instance, the event may have begun 1 ms before the time at which the current sample was captured.

### SUMMARY

The present disclosure relates generally to processing of sensor measurements. More specifically, and without limitation, techniques disclosed herein relate to time-aligning measurement samples from one sensor with measurement samples from one or more additional sensors. Techniques are also disclosed herein which relate to assigning timestamps to measurement samples in a system where a computing device processing the measurement samples and one or more sensors generating the measurement samples operate on different time domains.

In some embodiments, a system for time-alignment includes a reference signal generator, a first sensor, a second sensor, and one or more processing units. The reference signal generator is configured to output one or more reference signals. Each reference signal includes a reference marker followed by a sequence of alignment pulses. The first sensor is configured to capture a first set of measurement samples at regular intervals corresponding to a first sampling period. The first set of measurement samples includes direct or indirect measurements of a first reference signal in the one or more reference signals. Similarly, the second sensor is configured to capture a second set of measurement samples at regular intervals corresponding to a second sampling period. The second set of measurement samples includes direct or indirect measurements of the first reference signal or a different reference signal in the one or more reference signals. The one or more processing units are configured to time-align the first set of measurement samples to the second set of measurement samples through assigning a first timestamp to a first alignment pulse represented in the first set of measurement samples, relative to a first reference marker represented in the first set of measurement samples, and assigning a second timestamp to a second alignment pulse represented in the second set of measurement samples, relative to the first reference marker as represented in the second set of measurement samples.

In the above-described system, the first reference marker can include one or more pulses, where a duration of the first reference marker is at least two times longer than the first sampling period and the second sampling period.

In the above-described system, the first alignment pulse and the second alignment pulse can be different alignment pulses in a same sequence of alignment pulses.

In the above-described system, for each reference signal, alignment pulses in the sequence of alignment pulses can have a same pulse width and repeat according to a pulse period. Optionally, the pulse period can be longer than twice the first sampling period, the second sampling period, or both sampling periods. Optionally, the pulse period can be configured to not be an integer multiple of the first sampling period and/or not be an integer multiple of the second sampling period. Optionally, the pulse width can be shorter than the first sampling period, the second sampling period, or both sampling periods.

In the above-described system, the first set of measurement samples can include a sample representing a signal that is not a reference signal. The one or more processing units can be configured to assign a timestamp to the sample representing the signal that is not a reference signal, based on the first timestamp and the first sampling period.

In the above-described system, the first sensor and the second sensor can be configured to capture samples of the first reference signal such that the first set of measurement samples and the second set of measurement samples represent concurrent measurements of the first reference signal.

In some embodiments, an apparatus for time-alignment in accordance with the functionality of the above-described system includes, in addition to the one or more processing units, a communications interface configured to receive the first set of measurement samples and the second set of measurement samples. The apparatus may implement a computing device that is part of the first sensor or the second sensor. Alternatively, the apparatus may be external to the first sensor and the second sensor.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative embodiments are described in detail below with reference to the following figures.

FIG. 1 shows a block diagram of an example sensor system, according to some implementations.

FIG. 2 shows a block diagram of example aspects of a sensor system, according to some implementations.

FIGS. 3A and 3B show examples of reference signals, according to some implementations.

FIG. 4 shows an example of an alignment pulse being observed by a sensor, according to some implementations.

FIG. 5 shows an example of different reference signals being applied concurrently, according to some implementations.

FIG. 6 shows experimental measurements obtained by applying a reference signal to a pair of sensors.

FIG. 7 shows an example process for generating a reference signal, according to some implementations.

FIG. 8 shows an example process for time-aligning measurements from different sensors based on a reference signal, according to some implementations.

FIG. 9 shows a block diagram of a system for converting measurement samples from one time domain to another time domain, according to some implementations.

FIG. 10 shows an example implementation of a timestamp queue.

FIG. 11 shows an example process for translating timestamps between time domains, according to some implementations.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label with a second label that distinguishes among the similar components. If only the first reference label is used in the specification, the description is applicable to any one of the similar components having the same first reference label irrespective of the second reference label.

### DETAILED DESCRIPTION

The present disclosure relates generally to processing of sensor measurements. More specifically, and without limitation, techniques disclosed herein relate to time-aligning measurement samples from one sensor with measurement samples from one or more additional sensors. Techniques are also disclosed herein which relate to assigning timestamps to measurement samples in a sensor system where a computing device processing the measurement samples and one or more sensors generating the measurement samples operate on different time domains.

As used herein, the term “sample” or “measurement sample” refers to a set of data generated by a sensor. The set of data includes one or more numerical values, which are typically output in digital (e.g., binary) form by the sensor. The set of data can include a single measurement value, such as a voltage value. Alternatively, the set of data can include a collection of measurement values. For example, a digital camera can produce a two-dimensional array of pixel values corresponding to a frame of image data. Accordingly, a sensor can be any device configured to perform a measurement of some physical phenomenon and, in some instances, may include multiple sensing components such as an array of photodiodes.

A sensor can be configured to operate at a predetermined sampling frequency so that samples are captured at regular intervals corresponding to a sampling period of the sensor. The sampling frequency or period generally remains constant but may vary slightly over time. For example, changes in ambient temperature may increase or decrease the sampling frequency of a sensor by one percent or more. In some instances, the sampling frequency of a sensor can be varied, for example, through adjusting the output of a local clock of the sensor. A sample can include an instantaneous value observed by a sensor during a sampling time, where the sampling time coincides with the beginning or end of a sampling period. Some sensors may be configured to apply an integration window of fixed or variable length so that the value of a sample is a function of multiple observations over the duration of the integration window. The duration of the integration window can be shorter than the sampling period.

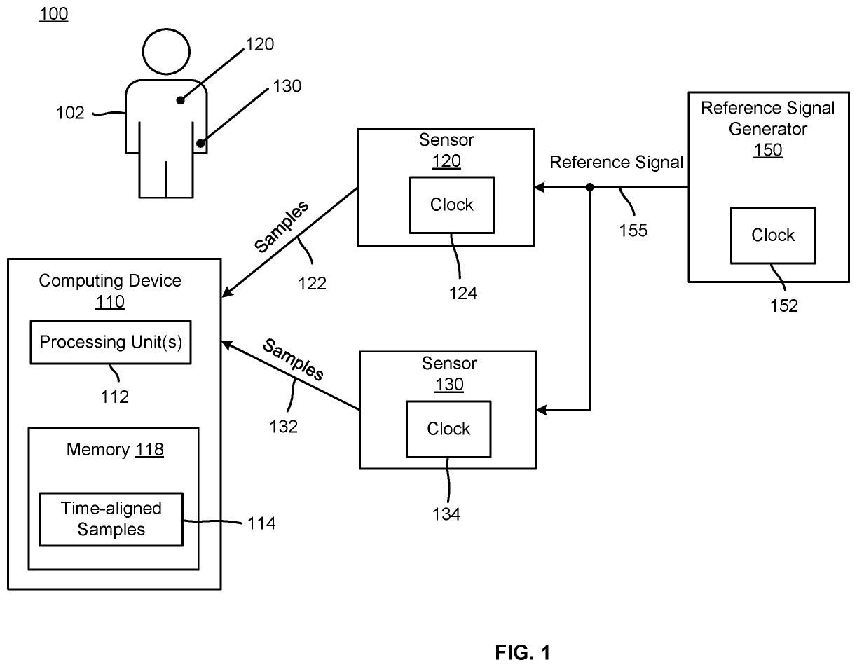

FIG. 1 shows a block diagram of an example sensor system 100, according to some implementations. The system 100 includes a computing device 110 configured to receive measurement samples from multiple sensors, including a first sensor 120 and a second sensor 130. The sensors 120, 130 can be configured to measure the same or different physical phenomena. For example, the sensor 120 can be an electrocardiogram (ECG) sensor that includes an electrode placed near the chest of a person 102 in order to detect the person's heartbeat. Sensor 130 may also detect the person's heartbeat but can use a different sensing mechanism and/or be placed at a different location relative to the person's body. For example, sensor 130 can be a photoplethysmography (PPG) sensor worn on a wrist or finger of the person 102 to optically measure pressure waves traveling through blood vessels near the skin's surface.

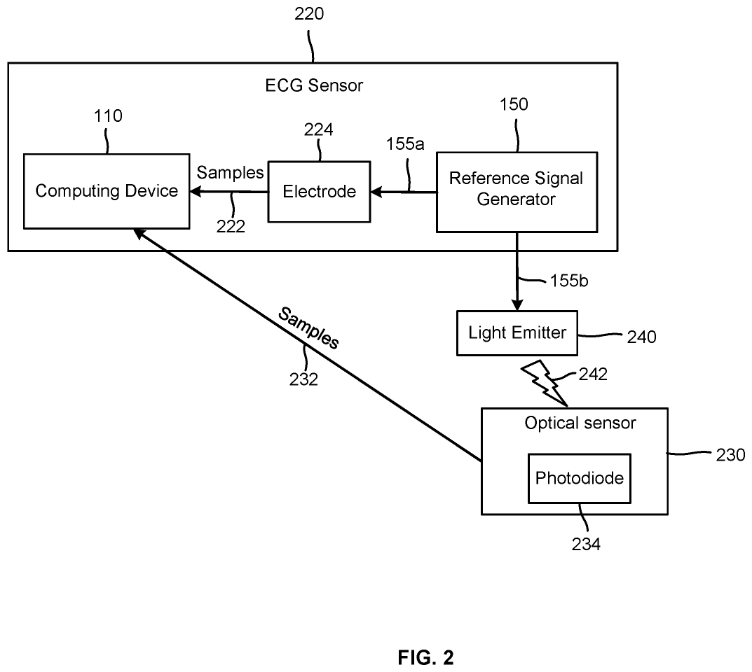

It should be noted that FIG. 1 provides only a generalized illustration of various components, any or all of which may be utilized as appropriate, and each of which may be duplicated as necessary. Specifically, although only two sensors are illustrated, it will be understood that any number of sensors may utilize the sensor system 100. The illustrated connections that connect the various components in the system 100 include data and signaling connections which may include additional (intermediary) components, direct or indirect physical connections and/or wireless connections. Furthermore, components may be rearranged, combined, separated, substituted, and/or omitted, depending on desired functionality. For example, a sensor can be combined with a reference signal generator, as shown in FIG. 2. Additionally, although the system 100 is described with respect to measurements of biological signals, sensors can be used in other contexts such as monitoring the performance of machinery or monitoring weather.

As shown in FIG. 1, sensor 120 can include a local clock 124 that determines the sampling frequency of the sensor 120. The clock 124 is configured to produce a clock signal, for example, a square wave with a predetermined duty cycle. The clock signal can be used as an input for triggering the capture of samples 122 by the sensor 120, e.g., on the rising or falling edges of the pulses in the clock signal. Clock 124 is typically implemented in hardware, for example, as a pulse generator circuit. Likewise, the sensor 130 can include a local clock 134 used for triggering the capture of samples 132 by the sensor 130. The clocks 124, 134 may operate at fixed frequencies or be programmable to vary the frequencies of the clock signals. The sampling frequency of the sensor 120 can be the same as or different from the sampling frequency of the sensor 130.

The sensors 120, 130 are communicatively coupled to a computing device 110 to provide the computing device 110 with samples 122 and samples 132, respectively. In some implementations, the samples received by the computing device may include embedded timestamps. For example, each sensor may include a microcontroller (not shown) that assigns a timestamp to the sensor's samples based a local clock of the sensor. The clock used to generate the timestamp is not necessarily the same clock that determines the sampling frequency, e.g., clock 124 or 134. For example, sensor 120 may include a real-time clock that measures the passage of time as a time of day or an elapsed time since the sensor 120 began producing the samples 122. The microcontroller may append the timestamps to the samples 122 as metadata. Alternatively, the sensor 120 may send the timestamps separately from the samples 122.

Computing device 110 may include one or more processing units 112 configured to process the samples 122, 132. The processing unit(s) 112 may, for example, execute an algorithm for time-aligning the samples 122 with the samples 132 to produce time-aligned samples 114. The algorithm can be part of a software program stored in a memory of the computing device 110, e.g., a memory 118 where the time-aligned samples 114 may also be stored. In addition to time-aligning the samples, the processing unit(s) 112 may also analyze the time-aligned samples 114, for example, to generate statistics or to perform certain actions in response to detecting the occurrence of events indicated by the time-aligned samples.

Not all sensors are configured to support synchronization. For example, synchronization techniques based on outputting a known, continuous-valued function such as a sine wave may not be possible if the microcontroller of a sensor is only capable of producing digital outputs, e.g., a square wave with discrete values between logic 0 (low) and logic 1 (high). In the absence of synchronization between the clocks used for timestamping at each sensor, or the absence of a mechanism for computing the difference between these clocks, it may be difficult for the processing unit(s) 112 to infer temporal relationships between the samples 122 and the samples 132. This is also true when one or more sensors are not configured to generate any timestamps. Further, even when there is a way to synchronize or compute the offset between timestamping clocks, the synchronization or offset computation may not be sufficiently accurate depending on the time scale over which events occur, relative to the resolution of the timestamping clocks. For example, if the smallest increment of time capable of being measured by a timestamping clock is one minute, aligning samples that are misaligned by less than one minute (e.g., several seconds) may not be possible.

The above-described example in which the sensors 120, 130 are in different locations relative to the body of the person 102 illustrates some of the challenges to time-alignment of measurements from different sensors. If the sensor 130 is a PPG sensor, the sensor can be configured to measure light absorption in a blood vessel. As the person's heart contracts, a pressure wave is generated that travels from the heart to the fingers. When the pressure wave passes by the location of the PPG sensor, the pressure wave is detected as a change in light absorption due to expansion of the blood vessel. If the sensor 120 is implemented as an ECG sensor with an electrode placed near the chest (for illustration purposes, assume there is only one electrode), the sensor 120 may detect electrical activity to produce an ECG waveform in which contractions of the heart, including the contraction corresponding to the pressure wave detected by the PPG sensor, are represented. Sensor 120 will capture the corresponding contraction sooner because the change in electrical activity due to the contraction takes less time to propagate to the electrode of the sensor 120 compared to the time it takes for the pressure wave to travel to the sensor 130.

The sensor 120 may measure the electrical activity as a change in voltage. The voltage change may be expressed numerically as a sample having a different value than the previous sample. However, the voltage change may have occurred anytime between the previous sample and the current sample. Therefore, there may be uncertainty as to the timing of events in measurement samples of any given sensor. Further, there may be additional uncertainty as to the time delay between corresponding events (e.g., heart contractions) at both sensor locations. In the above-described example, the time delay is typically on the order of a few milliseconds, which may be much shorter than the sampling period of either sensor 120, 130 (e.g., 10 ms). Without additional information, it may be difficult or even impossible to determine when an event was observed at the sensor 120 relative to a corresponding observation at the sensor 130. In order to enable the relative location in time of each sample produced by the sensors 120, 130 to be determined with greater precision, the sensors 120, 130 can be configured to measure a reference signal 155 produced by a reference signal generator 150, as shown in FIG. 1.

Reference signal generator 150 is configured to generate one or more reference signals, including the reference signal 155, for output to the sensor 120 and the sensor 130 concurrently. The reference signal generator 150 can be implemented in hardware or a combination of hardware and software, for example, using a microcontroller and/or digital logic circuits. The reference signal 155 can be communicated to the sensors 120, 130 through a shared signal path or separate paths. For instance, reference signal 155 can be output to sensor 120 as a first signal through a first output port of the reference signal generator while a second, identical signal is output in parallel to the sensor 130 through a second output port of the reference signal generator. In some implementations, at least one of the sensors 120, 130 receives the reference signal 155 wirelessly. Accordingly, the reference signal generator 150 may include a wireless communications interface with a wireless transmitter such as a Wi-Fi or Bluetooth transmitter.

The reference signal 155 can be a digital signal that includes a pattern of pulses. As described in further detail below, the pulse pattern for a reference signal may include one or more reference or fiducial markers that facilitate detection of the reference signal. The pulse pattern may further include an alignment sequence with a series of alignment pulses that have a fixed pulse period and a fixed pulse duration. The alignment pulses can be used to align the output of a sensor with the output of another sensor with greater precision than would otherwise be possible given the sampling periods of the sensors.

The reference signal 155 is measured by the sensors 120, 130 using the same sensing components that capture samples of interest, e.g., samples representing the user's heart activity. The reference signal 155 can be measured directly or indirectly. For example, the reference signal can be a voltage signal that is measured directly as a voltage. Alternatively, as described below with respect to the example of FIG. 2, the reference signal can be used as an input for generating some other signal that is measured by a sensor. In some implementations, the reference signal generator 150 outputs the reference signal 155 as part of a calibration procedure performed prior to capturing samples of interest. For instance, the calibration procedure can be performed prior to placing the sensors 120, 130 into operative positions with respect to the user's body. Alternatively or additionally, the reference signal 155 can be output to the sensors while capturing the samples of interest, e.g., so that the reference signal 155 is superimposed onto samples representing heart activity. So long as the reference signal 155 can be distinguished from the samples of interest, the reference signal can be filtered out, e.g., through processing performed by the computing device 110, to extract the samples of interest. The computing device 110 can be configured to recognize the reference signal 155 by, for example, storing the pulse pattern or characteristics of the reference signal into the memory 118 prior to obtaining the samples 122, 132.

In some implementations, a reference signal may be output to the sensors after capturing samples of interest. For example, the reference signal 155 may applied prior to capturing the samples of interest, and then the reference signal 155 or a different reference signal may be applied after the samples of interest have been captured. This would enable a correction factor to be computed for the sampling period of the sensor, which can potentially reduce timestamp error due to temperature induced changes in the sampling rate of one or more sensors. Accordingly, a reference signal can be applied before, during, and/or after capturing samples of interest. The same reference signal (i.e., an identical waveform) can be reapplied. Alternatively, different reference signals (e.g., a reference signal having a different pattern of alignment pulses) can be used.

The correction factor for the sampling period of a sensor can be computed through counting the actual number of observed samples and comparing this count to the expected number of samples between an earlier reference signal and a later reference signal, given the known sampling period of the sensor. As indicated above, the later reference signal can be identical to the earlier reference signal or a different reference signal altogether. The difference between the actual and expected counts can be used to calculate or recalculate timestamps based on an adjusted sampling period instead of the known sampling period. If the number of observed samples is higher than expected, this means the actual sampling rate is faster (shorter sampling period), so the known sampling period can be reduced accordingly. However, if the number of observed samples is lower than expected, this means the actual sampling rate is slower, so the known sampling period can be increased accordingly.

The adjusted sampling period can be used to timestamp samples captured between the earlier reference signal and the later reference signal. In some implementations, the adjusted sampling period is determined using reference signals that divide a measurement session into multiple time intervals, with samples of interest being captured in each of the intervals. In such implementations, the adjusted sampling period can be computed across the entire set of intervals, e.g., as an average sampling period, which would permit the value of the adjusted sampling period to be used for timestamping samples across every interval. Alternatively, an adjusted sampling period can be computed for a single interval or a sub-interval, for example, by considering each interval independently or by fitting a mathematical model (e.g., using linear interpolation) to the sample counts to derive a function that maps each sample to a respective sampling period value.

FIG. 2 shows a block diagram of example aspects of a sensor system, according to some implementations. The components depicted in FIG. 2 include an ECG sensor 220 and an optical sensor 230, which can be used to implement the sensor system 100 of FIG. 1. For example, ECG sensor 220 and optical sensor 230 may correspond to the sensor 120 and the sensor 130, respectively. In the example of FIG. 2, the computing device 110 and the reference signal generator 150 are integrated into the ECG sensor 220. In some implementations, the reference signal generator 150 generates the reference signal 155 using a local clock of the first sensor, e.g., the clock 124 in FIG. 1, and the sampling frequency of the ECG sensor 220 can be set using a lower frequency clock signal derived from the same local clock.

The reference signal generator 150 may output the reference signal 155 as a first signal 155a to an electrode 224 of the ECG sensor 220. For instance, the first signal 155a can be a digital signal that is 0 volts in the low state and 5 volts in the high state. Electrode 224 and its associated signal processing components (not shown) are configured to produce samples 222. For example, the electrode 224 may be coupled to an analog-to-digital converter that is clocked by a clock signal running at the sampling frequency of the ECG sensor. The samples 222 include observed portions of the first signal 155a. The observed portions are portions of the first signal 155a which coincide with sampling times of the ECG sensor 220.

As shown in FIG. 2, the reference signal generator 150 may output the reference signal 155 for measurement by the optical sensor 230 in the form of a second signal 155b that is received by a light emitter 240, e.g., a light-emitting diode. The second signal 155b can be the same as the first signal 155a and is output substantially simultaneously with the first signal 155a. However, it is not required that the signals 155a and 155b be identical, so long as they vary in a similar manner as a function of time. For instance, the second signal 155b could be a 12 volt signal having a similar pulse pattern as the first signal 155a. The light emitter 240 is configured to produce light 242 in response to the second signal 155b. The light 242 is sensed by a photodiode 234 of the optical sensor 230. Photodiode 234 and its associated signal processing components are configured to convert the light 242 into samples 232. Based on the example of FIG. 2, it will be understood that the generating of the reference signal 155 and/or the processing of samples can be performed locally by one of the sensors. FIG. 2 merely illustrates some of the ways in which a reference signal can be provided for concurrent measurement by different sensors. The reference signal or a signal derived from the reference signal can be input to a sensor in other ways, for example, by coupling the reference signal to a piezo-electric transducer to produce an acoustic signal measured by an audio sensor.

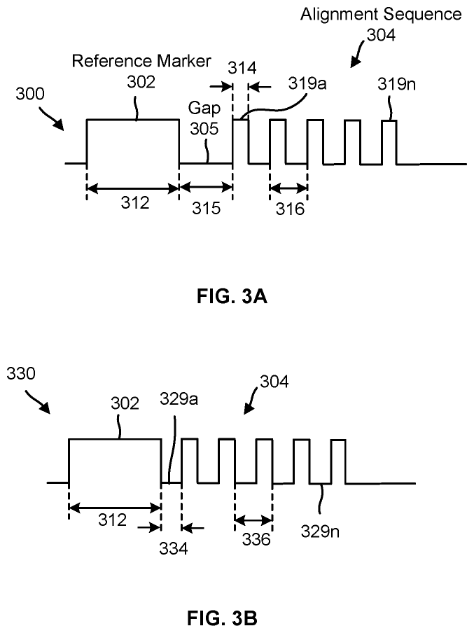

FIG. 3A shows an example of a reference signal 300, according to some implementations. The reference signal 300 can be used as the reference signal 155 and includes a reference marker 302 followed by an alignment sequence 304. The reference marker 302 and the alignment sequence 304 are separated by a gap 305 with a duration 315. The gap 305 corresponds to a period during which the reference signal 300 is low. In the example of FIG. 3A, the reference marker 302 consists of a single pulse with a duration 312. However, a reference marker can be configured with multiple pulses, e.g., as a pattern of pulses. The reference marker 302 serves to identify the start of the reference signal 300, e.g., based on the rising edge of the first (or only) pulse in the reference marker.

The alignment sequence 304 includes a series of alignment pulses 319, e.g., a first alignment pulse 319a and a last alignment pulse 319n. The alignment pulses 319 have a fixed (i.e., substantially uniform) pulse width 314 and repeat at a fixed interval corresponding to a pulse period 316. The total number of alignment pulses 319 in the alignment sequence 304 depends on implementation. For instance, the total number of alignment pulses can be as few as two but could feasibly be on the order of ten, a hundred, or even a thousand.

The duration 315 of gap 305 can be configured to permit the start of the alignment sequence 304 to be readily distinguished from the end of the reference marker 302. For example, if the duration 315 exceeds the sampling period of a sensor (e.g., every sensor in the system 100), this may ensure that the falling edge of the reference marker 302 and the rising edge of the first alignment pulse 319a do not occur within the same sampling period. It should be noted that the first alignment pulse 319a is not necessarily captured as a sample. For example, the first alignment pulse 310a may, in some instances, fail to coincide with any of the sampling times of a sensor. For time-alignment purposes, it may be sufficient that each sensor captures at least one alignment pulse 319 in addition to capturing the reference marker 302.

Example values for the reference signal 300 are as follows: reference marker 302 duration=100 ms, gap duration 315=100 ms, pulse width 314=1 ms, pulse period 316=101 ms.

FIG. 3B shows an example of a reference signal 330, according to some implementations. The reference signal 330 includes the alignment sequence 304 featured in the reference signal 300 but differs with respect to the portion of the reference signal preceding the alignment sequence. In the example of FIG. 3B, the reference signal 330 does not include a gap between the reference marker 302 and the alignment sequence 304. The start of the reference signal 330 is indicated by the rising edge of the reference marker 302, when the reference signal transitions from low to high. Similarly, the start of the alignment sequence 304 is indicated by the falling edge of the reference marker 302, when the reference signal transitions back to low. In contrast to FIG. 3A, alignment pulses 329 correspond to low states of the alignment sequence 304 instead of high states. Accordingly, an alignment pulse (e.g., a first alignment pulse 329a or a last alignment pulse 329n) may be observed when the alignment sequence 304 is low during a sampling time. Each alignment pulse 329 has a pulse width 334 and repeats according to a pulse period 336. A device that receives samples for processing (e.g., computing device 110) can be configured to treat either low states or high states as alignment pulses.

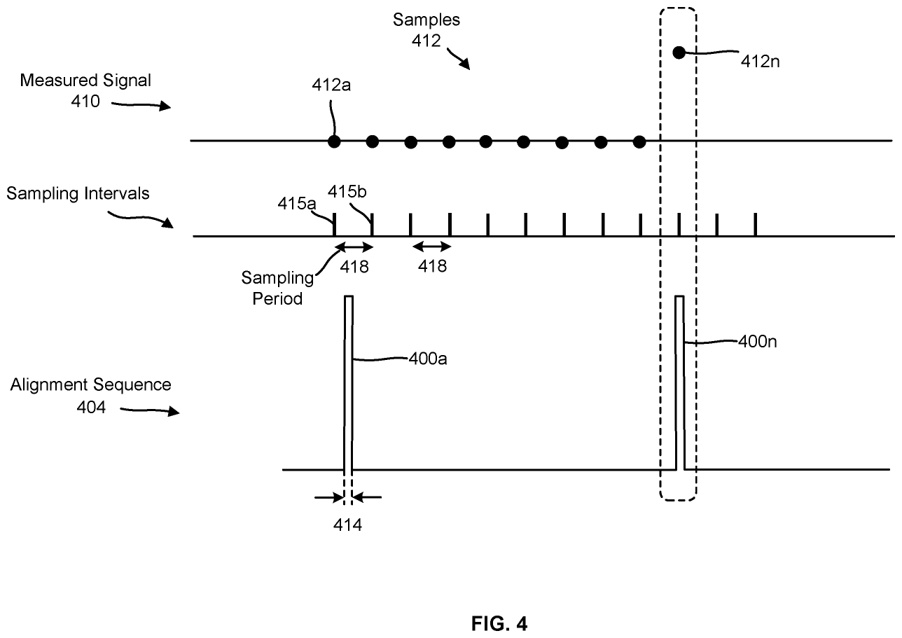

FIG. 4 shows an example of an alignment pulse 400n being observed by a sensor, according to some implementations. The alignment pulse 400n is part of an alignment sequence 404 and has a pulse width 414. In FIG. 4, a sensor generates a measured signal 410 that includes samples 412a and 412n. The samples 412 are output at regularly spaced intervals, which are denoted by tick marks 415 that are separated by a duration 418. Each tick mark 415 corresponds to the moment at which the sensor produces a measurement. Therefore, the duration 418 represents the sampling period of the sensor.

As shown in FIG. 4, the alignment sequence 404 includes an alignment pulse 400a that is unobserved. This is indicated by the fact that the samples 412 remain at zero throughout the entire duration of the alignment pulse 400a. The failure to observe the alignment pulse 400a may be due to lack of time coincidence between the alignment pulse 400a and any of the sampling times corresponding to the tick marks 415. Although the tick marks 415 are depicted as instantaneous moments in time, the duration over which a measurement is performed can be based on an integration window, as discussed above. In that case, the alignment pulse 400a may have missed an integration window around the time of the alignment pulse 400a. For example, the alignment pulse 400a could have begun after the end of an integration window associated with a tick mark 415a and ended before the start of an integration window associated with the next tick mark 415b.

Unlike the alignment pulse 400a, the alignment pulse 400n is successfully observed and thus represented as a sample 412n having a non-zero value. The alignment pulse 400n is able to be observed because it coincides with a sampling time associated with one of the tick marks 415. The pulse width 414 of the alignment pulses may be significantly shorter than the sampling period 418 of one or more sensors. For instance, the pulse width 414 can be configured to be several times smaller than the shortest sampling period among all the sensors in the system. When configured with pulse width 414 being shorter than the sampling period, the alignment sequence 404 operates similarly to a vernier scale, which has finer gradations than a main scale that is paired with the vernier scale. In this example, the main scale is analogous to the tick marks 415. The shortness of the pulse width 414 reduces the level of uncertainty regarding the time at which an observed event occurs. Here, the observed event is when the alignment pulse 400n coincides with a sampling time. However, unlike the tick marks on a vernier scale, the alignment pulses are not instantaneous. Further, the separation between alignment pulses (the pulse period) can be set longer than a sampling period, as discussed below. In contrast, the separation between the tick marks of a vernier scale is smaller than the separation between the tick marks of the main scale.

The time of coincidence can be ascertained as being the sampling time of the alignment pulse 400n, with a margin of error equal to the pulse width 414. For example, if the pulse width is 2 ms and it is known that the alignment pulse 400n starts 50 ms after the start of the reference marker (not shown in FIG. 4), it can be assumed that the sample 412n was taken at 50 ms. In actuality, however, the sample 412n may not represent the start of the alignment pulse 400n (e.g., the rising edge). For example, the sensor may have captured the end of the alignment pulse 400n (e.g., the falling edge), so that the alignment pulse 400n could have begun as much as 2 ms earlier than assumed. A reference signal having alignment pulses of appropriate pulse width can be selected to achieve a desired level of time-alignment precision. In general, the reference signal can be configured such that at least one alignment pulse is guaranteed to be observed by each sensor, thereby localizing the observed alignment pulses to a relatively narrow window defined by the pulse width. Additionally, as described below, other characteristics of a reference signal, such as pulse period, can be configured to facilitate time-alignment.

In some implementations, the characteristics of a reference signal are known to the device performing the time-alignment (e.g., computing device 110). When the characteristics of the reference signal are known, a set of samples from a first sensor can be timestamped by assigning a timestamp to a sample representing an observed alignment pulse, e.g., relative to the start of the reference marker portion of the reference signal. After assigning the timestamp to this sample, additional timestamps can be assigned to remaining samples, including subsequent samples representing heart activity or some other phenomenon of interest. The same process can be applied to a set of samples from a second sensor so that the timing of the samples from both sensors can be determined relative to the same reference point in time (e.g., the start of the reference marker).

Referring back to FIG. 3A, example characteristics of a reference signal that can be configured include reference marker duration (e.g., the pulse width of the reference marker 302), gap duration (e.g., duration 315), alignment pulse width (e.g., pulse width 314), alignment pulse period (e.g., pulse period 316), and total number of alignment pulses. The reference signal can be configured based on the known or expected sampling periods of the sensors in the system. In some implementations, a reference signal generator is preconfigured with multiple reference signals so that an appropriate reference signal can be selected for output to sensors, for example, selected by a user at the time of calibration. Alternatively or additionally, the reference signal generator may be tunable to vary one or more characteristics of the reference signal.

Reference marker duration: In some implementations, the reference marker duration spans multiple sampling periods. For example, the reference marker 302 may comprise a pulse that is at least two times longer than the longest sampling period among the sensors in the system. A relatively long reference marker reduces the likelihood that a sample representing the reference marker is mistakenly attributed to some other event, such as electrical noise, and makes the reference signal easier to identify among other recorded samples.

Gap duration: In some implementations, the gap length is longer than any sampling period among the sensors. For example, the gap 305 can be slightly longer than the longest sampling period. This may ensure that the falling edge of the reference marker 302 is observed as a sample and is distinguishable from the first alignment pulse (e.g., the rising edge of alignment pulse 319a).

Alignment pulse width: As indicated above, the alignment pulse width can be configured to be shorter than the shortest sampling period among all the sensors in the system, and the pulse width can be set equal to the desired time-alignment precision. Additionally, for sensors that apply an integration window to take measurements, the pulse width can be longer than the integration window so that the alignment pulses are easily distinguishable from electrical noise.

Alignment pulse period: In some implementations, the pulse period of the alignment pulses is longer than twice the longest sampling period. This ensures that there is no ambiguity as to which alignment pulse in the alignment sequence is the observed alignment pulse. For example, the pulse period (T) can be configured as follows:

$$T = ( n \times s ) + d \qquad ( 1 )$$

where n is any integer greater than 2, s is the longest sampling period, and d is some arbitrary positive number such that T is not an integer multiple of any sampling period among the sensors in the system. In one embodiment, d is equal to the duration of one alignment pulse, i.e., the pulse width.

To illustrate why having a pulse period longer than twice the sampling period resolves ambiguity in identifying an alignment pulse from among all the alignment pulses in an alignment sequence, consider the following example. Suppose that a sensor captures the following sequence of samples: 00111110000100000. In this example, the measurements are digital values, where a value of 0 (low) indicates no observation, and a value of 1 (high) indicates an observation. Assuming that the first set of observations (11111) corresponds to a reference marker, then the 1 value following the reference marker must be an alignment pulse. However, this observed alignment pulse could be any of the alignment pulses in the alignment sequence, i.e., not necessarily the first alignment pulse.

The actual time between the reference marker and the alignment pulse can be expressed as (N×s)±s, where N is the number of sampling periods from the end of the reference marker to the alignment pulse (in this example, N=5), and s is the sampling period of the sensor. The plus or minus term in this expression represents the uncertainty regarding the time between the reference marker and the alignment pulse. The uncertainty arises from the fact that the transition from low to high associated with the observed alignment pulse could have occurred any time within a sampling period (the time interval between consecutive samples). Similarly, the transition from high to low associated with the final observation of the reference marker could have occurred any time within a sampling period. Thus, the total uncertainty between these two observed events is 2×s.

Configuring the pulse period T to not be an integer multiple of the sampling period helps to a certain extent because each successive observed alignment pulse will have a different phase relationship (be phase-shifted) with respect to the sensor's sampling cycle. For example, suppose the sensor operates at 100 hertz (10 ms sampling period), the alignment pulse width is 1 ms, and the rising edge of the first alignment pulse coincides exactly with the instant a sample is taken, i.e., zero initial phase shift. Then the first alignment pulse will occupy the first 10% of the sampling period, the second alignment pulse will occupy the next 10% of the sampling period, and so on. Accordingly, it would take ten alignment pulses to occupy 100% of the sampling period, and only after ten alignment pulses (assuming there is an eleventh alignment pulse) would the phase relationship revert back to that of the first alignment pulse.

The possible times for the alignment pulses can be determined based on the known characteristics of the reference signal as well as the known sampling rate of the sensor, e.g., 110 ms, 121 ms, 132 ms, 143 ms, and so on. However, to ensure that an observed alignment pulse can be uniquely identified, there should only be one option among the list of possible times that lies within (N×s)±s. If the pulse period is longer than 2×s, that is, the total uncertainty, then it is guaranteed that only one of the possible times can be attributed to the observed alignment pulse. In this way, there will be exactly one alignment pulse that is active when a sample measurement is performed, regardless of any initial phase shift between the alignment sequence and the sensor's sampling cycle. Total number of alignment pulses: The number of alignment pulses is equal to s/d, rounded down to the nearest integer. The number of alignment pulses can be any integer greater than 1. In some implementations, an alignment sequence includes at least 10 alignment pulses. As the number of alignment pulses increases, the likelihood of a sensor observing multiple alignment pulses also increases. Although time-alignment can be performed based on only a single observed alignment pulse for each sensor, additional observed alignment pulses may serve as extra reference points for determining timing of measurement samples. In general, the number of alignment pulses has an inverse relationship with pulse width. When using a shorter pulse width, the number of alignment pulses can be increased to provide additional opportunities for the alignment pulses to coincide with sampling times.

Although the characteristics of a reference signal can be configured or selected based on the known sampling periods of the sensors, in practice the sampling period of a sensor may change based on temperature, manufacturing tolerances, and/or other factors. In some cases, the sampling period may be slightly longer than expected. Consequently, there may be instances where none of the alignment pulses are observed. One way to account for potential variation in sampling period is to set the number of alignment pulses to s′/d, where s′ is the largest possible sampling period that can be expected among all the sensors.

Another way to account for potential variation in sampling period is to set the term d in Equation 1 (shown above) equal to a fraction of the alignment pulse width. This can be done alone or in combination with setting the number of alignment pulses to s′/d. When d is set to a fraction of the pulse width, the contribution of d to the phase shift between the alignment pulses and the sensor's sampling cycle is less than one alignment pulse width each alignment pulse. This creates additional opportunities for the alignment pulses to coincide with sampling times, possibly resulting in observation of multiple alignment pulses. For example, if d is one-tenth of the pulse width, then 10 successive alignment pulses could potentially coincide with a sampling time.

One benefit to observing multiple alignment pulses is that the observations can be combined to provide even greater time-alignment precision. For instance, suppose alignment pulse numbers 3 to 7 are observed (five observed alignment pulses). This implies that the sampling events were centered approximately around alignment pulse 5, the middle alignment pulse in the set of observed alignment pulses. If alignment pulse 5 is used as the basis for assigning timestamps, then the error attributed to uncertainty regarding when each alignment pulse was observed will be reduced from one pulse width to one-fifth of a pulse width.

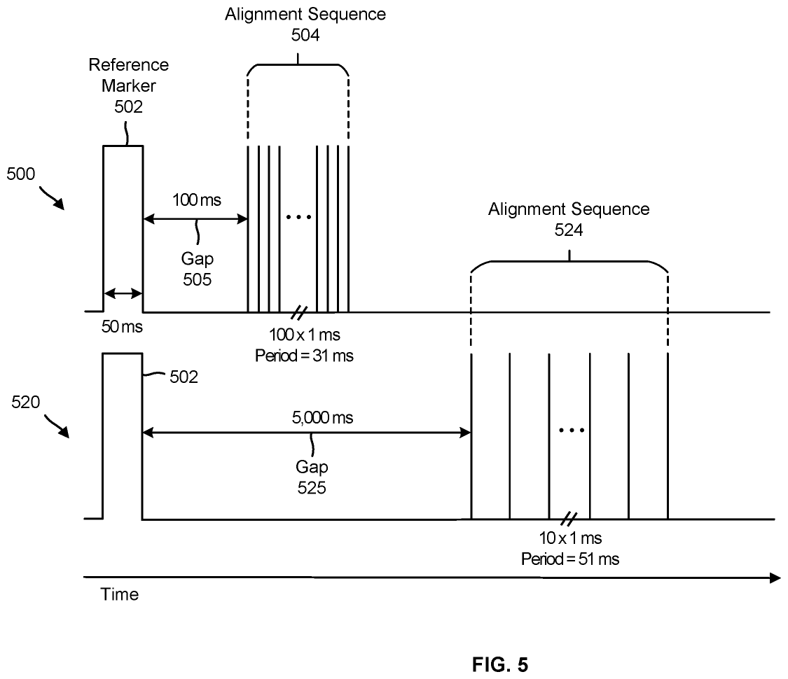

The timestamping process described above in reference to the sensor system of FIG. 1 involves applying the same reference signal (155) concurrently to each sensor being time-aligned. However, as indicated in the example of FIG. 2, separate reference signals (155a and 155b) can also be used, where the reference signals are not necessarily identical, but the reference signals at least vary in a similar manner as a function of time. Additionally, another option is to use a set of reference signals in which the alignment pulse pattern differs between two or more reference signals, but the reference marker portion of every reference signal in the set of reference signals is the same. In other words, the reference marker can be identical across reference signals, but the alignment sequence can differ, and an alignment sequence in one reference signal need not overlap or coincide with an alignment sequence in another reference signal. An example of this additional option is shown in FIG. 5.

FIG. 5 shows an example of different reference signals 500 and 520 being applied concurrently, according to some implementations. The reference signals 500 and 520 are similar to the reference signal 300 in FIG. 3A and each include a reference marker followed by a gap. In this example, the reference signal 500 includes a reference marker 502 that is 50 ms long and a gap 505 of 100 ms. The reference signal 500 further includes an alignment sequence 504 with one hundred alignment pulses, a pulse width of 1 ms, and a pulse period of 31 ms. Due to the relatively short pulse width, the alignment pulses are depicted as instantaneous impulses.

Like the reference signal 500, the reference signal 520 includes the reference marker 502. The reference markers 502 are depicted as coinciding with each other. The time coincidence between the reference markers 502 may be a result of outputting both reference signals 500, 520 concurrently such that the reference signal 500 and the reference signal 520 begin at approximately the same time, e.g., with the actual start times being permitted to differ by as much as the desired time-alignment precision. As shown in FIG. 5, the reference signal 520 further includes an alignment sequence 524 that is spaced apart from the reference marker 502 by a gap 525 that is longer (e.g., 5,000 ms) than the gap 505 in the reference signal 500. Thus, the alignment sequence 524 begins later relative to start of the reference signal 520, but the relative timing of both alignment sequences 504, 524 is known. The alignment sequence 524 includes ten alignment pulses having the same pulse width as the pulses in the alignment sequence 504 (1 ms). However, the alignment sequence 524 has a longer pulse period of 51 ms.

The characteristics of both reference signals 500, 520 (e.g., gap duration, pulse period, pulse width) can generally be determined according to the constraints described above in connection with FIG. 3A. However, at least some of the characteristics of each reference signal may be tailored for the specific sensor to which the reference signal is applied. For example, the duration of gap 505 can be longer than the sampling period of the optical sensor 230, the pulse width for the alignment sequence 504 can be shorter than the sampling period of the optical sensor 230, and the pulse period for the alignment sequence 504 can be longer than twice (and not an integer multiple of) the sampling period of the optical sensor 230. Similarly, the duration of gap 525 can be longer than the sampling period of the ECG sensor 220, the pulse width for the alignment sequence 524 can be shorter than the sampling period of the ECG sensor 220, and the pulse period for the alignment sequence 524 can be longer than twice (and not an integer multiple of) the sampling period of the ECG sensor 220.

Using reference signals with different alignment sequences can avoid situations where, due to differences in sampling rate and/or other sensor attributes, alignment pulses are difficult to identify from the captured samples. For instance, it is possible that applying the reference signal 500 to the ECG sensor 220 instead of the reference signal 520 would produce numerous observations of the alignment sequence 504 that are spaced so closely together that the alignment pulses are indistinguishable. To prevent this potential blending together of the alignment pulses, a reference signal (e.g., reference signal 520) with a longer pulse period may be applied to the ECG sensor.

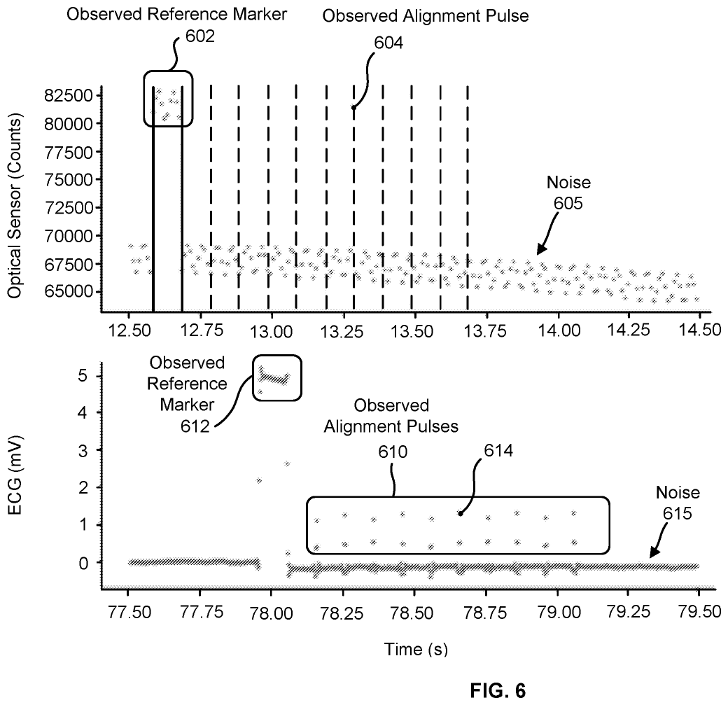

FIG. 6 shows experimental measurements obtained by an ECG sensor and an optical sensor. Each dot corresponds to a sample. The output of the ECG sensor is expressed in millivolts (mV), and the output of the optical sensor is expressed as count values. In the example of FIG. 6, the same reference signal was used for both sensors. The optical sensor captured a set of samples 602 corresponding to a reference marker and a sample 604 corresponding to an alignment pulse. Additional captured samples correspond to electrical noise 605. The optical sensor operated at 100 hertz (Hz) to produce samples at a sampling period of 10 ms. The vertical lines in the plot of the optical sensor's measurements indicate 100 ms intervals, with the first two (solid) lines corresponding to the start and end of the reference marker. In the example of FIG. 6, the alignment sequence includes ten alignment pulses. The sample 604 represents an observation of the sixth alignment pulse, around 13.25 seconds in the optical sensor's time domain. The remaining nine alignment pulses were unobserved cause they failed to coincide with any of the optical sensor's sampling times.

The ECG sensor in FIG. 6 operated at 500 Hz to produce samples at a sampling period of 2 ms. The ECG sensor captured a set of samples 612 corresponding to the same reference marker observed by the optical sensor. The ECG sensor also captured a set of samples 610 representing observations of all ten alignment pulses, including a sample 614 corresponding to the sixth alignment pulse. All ten alignment pulses were observed as a result of processing by a filtering stage in the ECG sensor. The filtering stage distorted the alignment pulses such that the pulse widths were longer than the sampling period (2 ms). Like the measurements of the optical sensor, the measurements of the ECG sensor include noise 615. As shown in FIG. 6, events observed by the ECG sensor were sampled at times different from the times at which corresponding events were sampled by the optical sensor. For example, the reference marker was not observed until around 78 seconds in the ECG sensor's time domain.

In some implementations, samples from a first sensor can be time-aligned to samples from a second sensor as follows. An alignment pulse observed by the first sensor is identified (e.g., sample 604). An index number is then assigned to this observed alignment pulse. For instance, if the first alignment pulse corresponds to index 0, then the sixth alignment pulse would be assigned index 7. The alignment pulse can be identified based on the known characteristics of the reference signal. For instance, given knowledge of when the first alignment pulse begins with respect to the reference marker, as well as the pulse width and pulse period of the alignment pulses, a list of possible times for the alignment pulses can be calculated to determine which alignment pulse in the alignment sequence was the observed alignment pulse.

After assigning the index number, the sample associated with the observed alignment pulse can be assigned a timestamp t:

$$t = r + g + m \times T \qquad ( 2 )$$

where r is the duration of the reference marker, g is the gap duration, m is the index of an observed alignment pulse, and T is the pulse period of the alignment pulses. In this manner, the time value of the observed alignment pulse can be calculated relative to the start of the reference marker. For instance, the leading (e.g., rising) edge of the reference marker can be treated as corresponding to a timestamp t_{Ref}=0. Timestamps can then be assigned to the remaining samples observed by the first sensor, including samples not associated with the reference signal, using the known sampling rate of the sensor. For instance, the next sample after the observed alignment pulse would be assigned a timestamp equal to t+s₁, then t+2s₁, t+3s₁, and so on, where s₁ is the sampling period of the first sensor.

The above-described timestamping procedure can be repeated for the samples from the second sensor so that the resulting timestamps can be directly compared to the timestamps of the first sensor to derive temporal relationships between the samples of both sensors. Note, it is not necessary for the alignment pulse observed by the first sensor to be the same alignment pulse observed by the second sensor since the timestamps for both sensors can all be calculated relative to the reference marker. For example, the alignment pulse used to calculate t for the ECG sensor in FIG. 6 could be the sixth alignment pulse (sample 614), but any of the other nine alignment pulses observed by the ECG sensor would also be suitable.

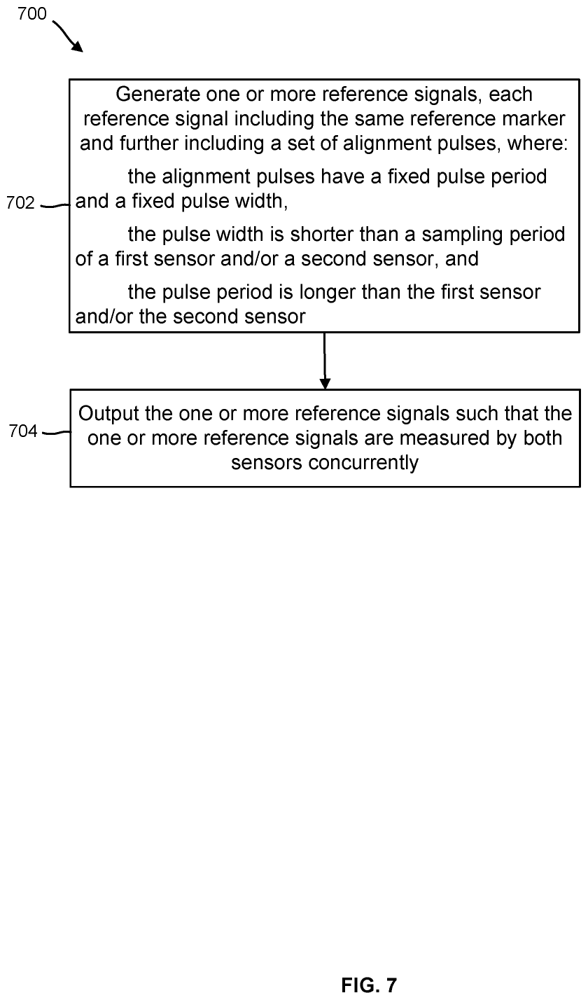

FIG. 7 shows an example process 700 for generating a reference signal, according to some implementations. In the example of FIG. 7, the reference signal is used to time-align measurements from a first sensor to measurements from a second sensor. However, the process 700 can be applied to any plurality of sensors. The process 700 can be performed by a reference signal generator (e.g., reference signal generator 150). The reference signal generator can be integrated into a sensor or external to both the first sensor and the second sensor. At 702, the reference signal generator generates one or more reference signals. Each reference signal includes the same reference marker and further includes a set of alignment pulses. A reference signal generated at block 702 may, for example, correspond to one of the reference signals depicted in FIGS. 3A, 3B, or FIG. 5.

The set of alignment pulses within a reference signal generated in block 702 can be configured according to the constraints described above so as to include alignment pulses that have a fixed (substantially uniform) pulse width and a fixed pulse period. The pulse width is shorter than a sampling period of one or more sensors, e.g., shorter than the sampling period of the first sensor, the sampling period of the second sensor, or both. The pulse width may be set according to a desired time-alignment precision. In contrast to the pulse width, the pulse period is set longer than the sampling period of one or more sensors, e.g., more than twice as long as the sampling period of the first sensor and/or the second sensor. In some implementations, the reference generator may be preconfigured (e.g., programmed) with a set of reference signals that have different characteristics such as reference marker pulse pattern, reference marker pulse duration, gap duration, alignment pulse period, and/or alignment pulse width. The set of reference signals can be made available for selection by a user (e.g., a person operating the sensors) through a user interface of the reference signal generator. Alternatively or additionally, the user interface may permit the user to manually configure one or more characteristics of the reference signal, for example, to fine-tune the alignment pulse width of one of the preconfigured reference signals.

At 704, the reference signal generator outputs the one or more reference signals such that the reference signal(s) are measured by both sensors concurrently. The manner in which a reference signal is measured depends on the configurations of the first sensor and the second sensor. For example, a reference signal may be provided directly to a sensor for measurement, as with the ECG sensor 220 in FIG. 2. Alternatively, a reference signal may be used to derive a second signal corresponding to a physical (e.g., electrical, electromagnetic, acoustic, or thermal) phenomenon measured by a sensor, as with the optical sensor 230. In some implementations, the reference signal generator is temporarily coupled to a sensor or an intermediate device, for example by electrical cable or through a wireless pairing procedure. The reference signal generator may be uncoupled after outputting the reference signal in block 704, described below. In some implementations, the functionality in blocks 702 and 704 is performed as part of a calibration process in which the sensors that are to be time-aligned measure the one or more reference signals before and/or after capturing samples of interest. Alternatively or additionally, the one or more reference signals can be measured simultaneously with the samples of interest and then filtered out.

The reference signal generator can output a reference signal along a shared path or along separate paths. When using separate paths, the reference signal generator can be configured to output separate instances of a reference signal simultaneously along each path. For example, a reference signal can be output as parallel signals through different output ports of the reference signal generator. Further, the parallel signals are not necessarily identical. For instance, the parallel signals may have pulse patterns that vary in a similar manner as a function of time, but the amplitudes of the parallel signals may differ. Depending on propagation delay, the first sensor may observe the reference signal or derivative at a different time than the second sensor.

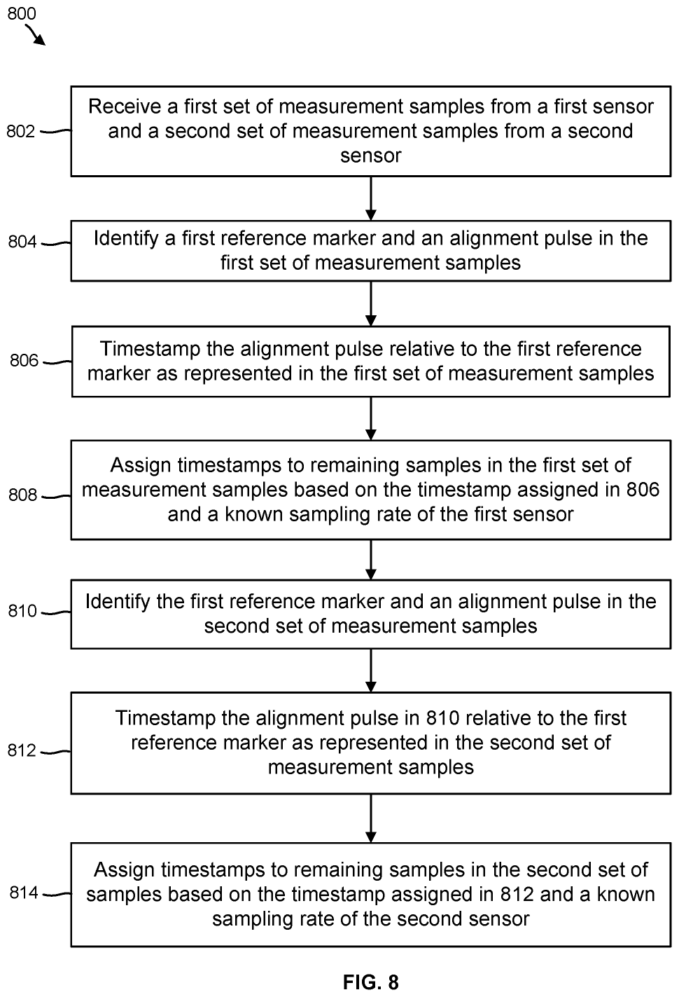

FIG. 8 shows an example process 800 for time-aligning measurements from different sensors based on a reference signal, according to some implementations. In the example of FIG. 8, one or more reference signals are used to time-align measurements from a first sensor to measurements from a second sensor. However, the process 800 is scalable for time-aligning measurements from any plurality of sensors. The process 800 can be performed by a computing device (e.g., computing device 110) that receives measurement samples from the first sensor and the second sensor. The computing device can be integrated into a sensor or external to both the first sensor and second sensor. In some implementations, the process 800 is performed as part of post-processing after the first sensor and the second sensor have finished capturing all their measurement samples. Alternatively, the computing device may receive samples in substantially real-time so that the computing device can compute at least a starting timestamp for each sensor while the first sensor and the second sensor are still capturing samples.

At 802, the computing device receives a first set of measurement samples from the first sensor and a second set of measurement samples from the second sensor. The first set of measurement samples includes samples representing direct or indirect measurements of a first reference signal. Similarly, the second set of measurement samples includes samples representing direct or indirect measurements of the first reference signal or a different reference signal. The reference signal(s) are observed by the first sensor and the second sensor concurrently, but not necessarily simultaneously.

At 804, the computing device identifies a first reference marker and an alignment pulse in the first set of measurement samples. As discussed above, a reference signal may include a reference marker followed by a set of alignment pulses. With appropriate configuration of the reference signal, each sensor is able to observe both the reference marker and at least one alignment pulse. With respect to the reference marker, the sensor should be able to observe high-to-low or low-to-high transitions associated with the beginning and the end of the reference marker. However, these observed transitions need not coincide with the actual edge transitions of the reference marker. Although the observations of the reference marker are subject to the uncertainty discussed above with respect to the alignment pulses (where the transition can happen anywhere between two consecutive samples), the uncertainty can be resolved through the timestamping procedure in block 806, discussed below. As for the alignment pulses, in some instances, the first sensor and/or the second sensor may observe multiple alignment pulses. In such instances, the computing device may identify more than one alignment pulse. In the context of the time-alignment process in FIG. 8, identifying an alignment pulse means determining which alignment pulse among a set of alignment pulses was observed by the sensor.

At 806, the computing device timestamps the alignment pulse relative to the first reference marker as represented in the first set of measurement samples. The timestamping of the alignment pulse can be based on known characteristics of a reference signal, for example, the duration of the first reference marker and the pulse period and pulse width of the alignment pulses in the reference signal. For instance, the alignment pulse may be assigned a timestamp with respect to the start (e.g., rising edge) of the first reference marker, as discussed above. To identify the start or end of the first reference marker, the phase shift between the rising and/or falling edges of the first reference marker and the sampling cycle of the sensor can be determined based on the index number of the observed alignment pulse. In the case of zero phase shift, the observed alignment pulse could be the first alignment pulse (index 0). As the phase shift between the first reference marker and the sampling cycle increases, so does the index. Accordingly, the timestamp assigned to the alignment pulse in block 806 can be determined through identifying which alignment pulse was observed, using the index of the identified alignment pulse to determine when an edge transition in the first reference marker actually occurred, assigning a timestamp value to this edge transition (e.g., a time of 0 for the edge corresponding to the beginning of the first reference marker), and then calculating the timestamp for the alignment pulse as an offset value relative to the timestamp of the first reference marker. Alternatively, the timestamp can be expressed as a time value in a time domain of the computing device. For example, in implementations where the measurement samples are communicated to the computing device in real-time, the computing device may assign a receive timestamp to the first reference marker using a local clock of the computing device. The timestamp for the alignment pulse can then be calculated by adding the offset value to the value of the first reference marker's timestamp.

At 808, the computing device assigns timestamps to remaining samples in the first set of measurement samples, based on the timestamp assigned to the alignment pulse in block 806 and a known sampling rate of the first sensor. The remaining samples may include additional alignment pulses observed by the first sensor. In some instances, the remaining samples include samples of interest, e.g., samples representing heart activity or some other physical phenomenon besides the reference signal itself. The timestamps for the remaining samples can be calculated by, for example, incrementing the value of the timestamp from block 806 by the sampling period of the first sensor to compute the timestamp for each subsequent sample.

At 810, the computing device identifies the first reference marker and an alignment pulse in the second set of measurement samples. As discussed above in reference to FIG. 6, the alignment pulse observed by the first sensor does not have to be the same alignment pulse observed by the second sensor. For example, the first sensor may have observed the first alignment pulse, and the second sensor may have observed the sixth alignment pulse. The observed alignment pulses will also be different when a different pattern of alignment pulses is applied to the first sensor than the second sensor, e.g., when each sensor measures a different reference signal.

At 812, the computing device timestamps the alignment pulse that was identified in block 810, relative to the first reference marker as represented in the second set of measurement samples. The timestamping of the alignment pulse can be performed in the same manner as in block 806. In cases where the alignment pulse identified in block 810 is the same as the alignment pulse identified in block 812, the computing device may simply assign the same timestamp from block 806 so as not to repeat the calculation.

At 814, the computing device assigns timestamps to remaining samples in the second set of measurement samples, based on the timestamp assigned to the alignment pulse in block 812 and a known sampling rate of the second sensor. The assignment of the timestamps in block 814 can be performed in the same manner as in block 808.

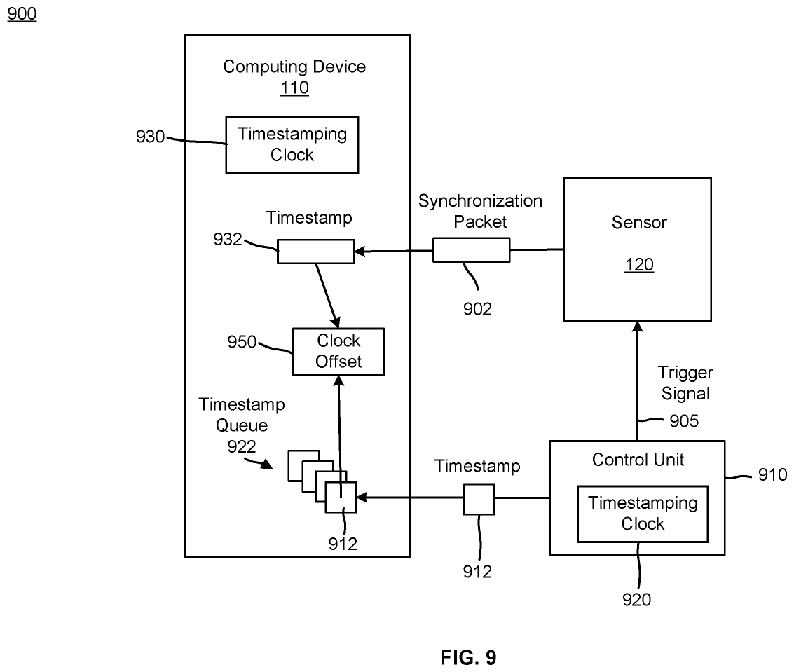

FIG. 9 shows a block diagram of a system 900 for converting measurement samples from one time domain to another time domain, according to some implementations. The system 900 includes components of the system 100 from FIG. 1, such as the sensor 120. In FIG. 9, only one sensor is shown for simplicity. However, the functionality described with respect to the sensor 120 in FIG. 9 can also be applied to other sensors in the system 100, such as the sensor 130. In the example of FIG. 9, samples captured by the sensor 120 are timestamped twice, once by a control unit 910, and again by the computing device 110.

Control unit 910 is configured to output a trigger signal 905 to the sensor 120. The control unit 910 can be implemented as one or more processing units that are part of or communicatively coupled to the sensor 120. For example, the control unit 910 can be a microcontroller of a digital camera including an image sensor array corresponding to the sensor 120. In some implementations, the control unit 910 may be configured to provide trigger signals to multiple sensors, e.g., trigger signals that are output in parallel in a similar manner to the above-described parallel output of reference signals. The trigger signal 905 is a timing control signal that causes the sensor 120 to output a synchronization packet 902. Like the reference signals described above, the trigger signal 905 can be a digital signal that includes a pattern of pulses. Alternatively, the trigger signal 905 can be a single pulse of predetermined width. The trigger signal 905 can also be a digital message. For instance, the trigger signal could be a message-signaled interrupt.

The synchronization packet 902 can be a measurement sample. Alternatively, the sensor 120 may be configured to generate the synchronization packet 902 according to a pattern that is known to the computing device 110. For instance, the synchronization packet 902 can be a message with a payload that distinguishes the synchronization packet from measurement samples.

As shown in FIG. 9, the control unit 910 includes a timestamping clock 920. The control unit 910 is configured to generate timestamps corresponding to the output times of the sensor 120. The timestamps generated by the control unit 910 include a timestamp 912 corresponding to an output time of the synchronization packet 902 as measured based on the timestamping clock 920. The control unit 910 can also generate timestamps for measurement samples captured by the sensor 120, e.g., timestamps that indicate sampling times. Accordingly, the timestamping clock 920 represents a time domain of the sensor 120.

The control unit 910 can send the timestamp 912 to indicate the time value for a “start of frame” event corresponding to the outputting of the synchronization packet 902. A start of frame event can also correspond to the outputting of a sequence of measurement samples by the sensor 120. The timestamps generated by the control unit 910 are transmitted to the computing device 110, which places the timestamps into a timestamp queue 922. The timestamps generated by the control unit 910 are transmitted separately from any measurement samples, e.g., through a side channel. One reason for the separate transmission of the timestamps is that measurement samples from the sensor 120 may be output in a format that does not support embedded timestamps. For instance, the samples may lack a metadata field for including timestamp information. In such instances, the timestamp queue 922 can operate as a buffer for temporarily storing timestamps associated with samples from the sensor 120 in addition to storing the timestamp 912 associated with the synchronization packet 902.

Computing device 110 is configured to receive output from the sensor 120, including the synchronization packet 902 as well as measurement samples. In some implementations, the computing device 110 is communicatively coupled to the sensor 120 to receive samples in substantially real-time, e.g., as a stream of samples that are output concurrently with capturing of additional samples by the sensor 120. When the computing device 110 receives an output of the sensor 120, the computing device can assign a timestamp corresponding to a receive time as measured based on a timestamping clock 930 of the computing device. For example, upon receiving the synchronization packet 902, the computing device may assign a timestamp 932 to the synchronization packet. The timestamp 932 assigned by the computing device may differ from the timestamp 912 assigned by the control unit 910. If so, then the computing device 110 can compute a clock offset 950 corresponding to the difference between these timestamps.

The computing device 110 can use the clock offset 950 to match subsequently received samples (not shown) to corresponding timestamps in the timestamp queue 922, thereby correlating the received samples with the timestamps provided by the control unit 910. The computing device 110 can receive the samples based on output of a separate trigger signal from the control unit 910. The separate trigger signal can be a signal that instructs the sensor 120 to begin outputting samples at regular intervals corresponding to the sampling period of the sensor 120, similar to the function of the trigger signal 905 with respect to output of the synchronization packet 902.

Upon finding a matching timestamp in the timestamp queue 922, the computing device can tag the received samples with their corresponding timestamps, e.g., by replacing a timestamp assigned based on the clock 930 with a timestamp assigned based on the clock 920. In this manner, the computing device 110 may translate the timestamp of a sample from the time domain of the computing device 110 to the time domain of the sensor 120.

The computing device 110 can use the timestamp tags to process the received samples, for example, to render the samples as video on a display screen with a timing in accordance with the values of the timestamp tags. The translation of timestamps from the time domain of the computing device to the time domain of the sensor 120 can be performed in combination with time-aligning the samples from the sensor 120 to samples from another sensor, e.g., the sensor 130, as described above. For example, the sensor 120 may capture images while the sensor 130 captures audio. By time-aligning audio from the sensor 130 to images from the sensor 120, the computing device 110 may combine the audio and the images to render video in which image frames are output concurrently with corresponding audio segments. The computing device 110 can align the audio and the images based on one or more reference signals, e.g., the reference signal 155 and in accordance with the process in FIG. 8. The one or more reference signals may permit the audio and the images to be time-aligned with a greater precision compared to the timestamps generated using the timestamping clock 920. For example, the timestamping clock 920 may be a real-time clock that measures time of day with a minimum increment of one second, whereas the alignment pulses of the reference signal 155 may be configured to provide sub-seconds alignment precision.

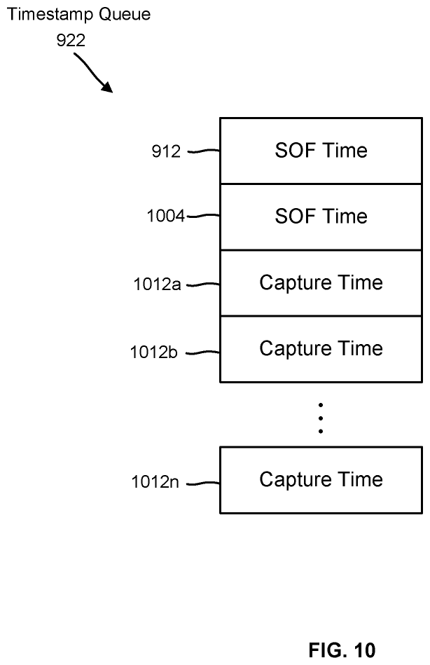

FIG. 10 shows an example implementation of the timestamp queue 922. The timestamp queue 922 includes the timestamp 912 and other timestamps provided by the control unit 910. In FIG. 10, the timestamp 912 indicates a start of frame (SOF) time corresponding to an output time of the synchronization packet 902. The timestamp 912 is followed by an SOF time 1004 and a set of capture times 1012a to 1012n. The SOF time 1004 may be a time associated with the outputting of a sample captured after the synchronization packet 902 has been output. For instance, the SOF time 1004 may correspond to the first image in a sequence of images to be rendered by the computing device 110, and the capture times 1012 may correspond to subsequent images in the sequence of images. The computing device 110 may correlate the first image to the SOF time 1004 by using the clock offset 950 to adjust a timestamp generated for the first image based on the timestamping clock 930. Likewise, the computing device 110 may correlate a second image in the sequence of images to one of the capture times 1012 by using the clock offset 950 to adjust a timestamp generated for the second image based on the timestamping clock 930. Alternatively, the computing device 110 may identify a capture time 1012 through incrementing the SOF time 1004 by a known frame rate of the sensor, e.g., the sampling period of the sensor 120.

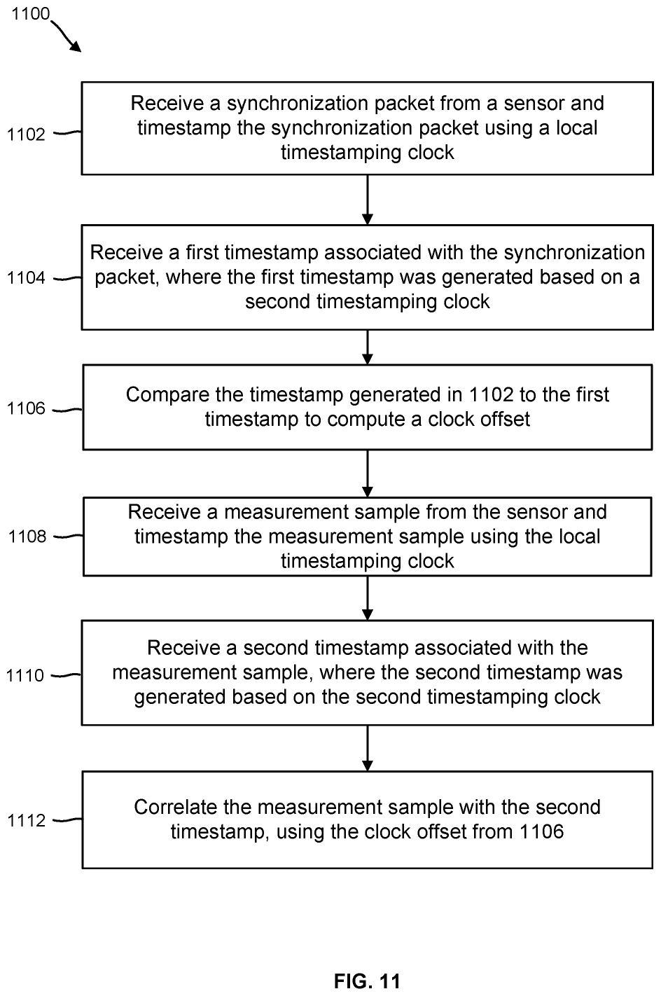

FIG. 11 shows an example process 1100 for translating timestamps between time domains, according to some implementations. The process 1100 can be performed by a computing device (e.g., computing device 110) that receives measurement samples from at least one sensor and timestamps the measurement samples using a timestamping clock of the computing device. At 1102, the computing device receives a synchronization packet from a sensor (e.g., the synchronization packet 902) and timestamps the synchronization packet using the timestamping clock of the computing device (e.g., the clock 930).

At 1104, the computing device receives a first timestamp associated with the synchronization packet. The first timestamp is a timestamp generated based on a second timestamping clock (e.g., the clock 920) and corresponds to an output time of the synchronization packet.

At 1106, the computing device compares the timestamp generated in block 1102 to the first timestamp to compute a clock offset.

At 1108, the computing device receives a measurement sample from the sensor and timestamps the measurement sample using the timestamping clock of the computing device.

At 1110, the computing device receives a second timestamp associated with the second sample. Like the first timestamp from block 1104, the second timestamp is a timestamp that was generated based on the second timestamping clock and, in this instance, corresponds to an output time of the measurement sample. The first timestamp and the second timestamp may be stored in a memory of the computing device, for example, a memory implementing the timestamp queue 922.

At 1112, the computing device correlates the measurement sample with the second timestamp, using the clock offset that was computed in block 1106. For instance, the clock offset can be used to adjust the timestamp generated in block 1108, thereby producing an adjusted timestamp that can be matched to the second timestamp. In some implementations, the correlation involves iterating through the timestamp queue 922 to locate a timestamp that matches the adjusted timestamp. The timestamp in the timestamp queue 922 does not have to be an exact match. In some implementations, the adjusted timestamp and the timestamp in the timestamp queue can differ slightly (e.g., within one second of each other) and still be deemed to match.

The embodiments described herein may be used in conjunction with various technologies, such as an artificial reality system. An artificial reality system, such as a head-mounted display (HMD) or heads-up display (HUD) system, generally includes a display configured to present artificial images that depict objects in a virtual environment. The display may present virtual objects or combine images of real objects with virtual objects, as in virtual reality (VR), augmented reality (AR), or mixed reality (MR) applications. For example, in an AR system, a user may view both displayed images of virtual objects (e.g., computer-generated images (CGIs)) and the surrounding environment by, for example, seeing through transparent display glasses or lenses (often referred to as optical see-through) or viewing displayed images of the surrounding environment captured by a camera (often referred to as video see-through). In some AR systems, the artificial images may be presented to users using a light emitting diode (LED) based display subsystem. Accordingly, at least some of the sensors described herein may correspond to a sensor that is part of, or in communication with, an artificial reality system. For example, the sensor 120 can be a camera or other sensor in an HMD, and the sensor 130 can be an optical or other sensor in a wristwatch worn by the same user wearing the HMD. The HMD and the wristwatch can be communicatively coupled to each other and/or to a separate computing device such as a smartphone or personal computer configured to process (e.g., time-align) measurement samples captured by the sensors of the HMD and the wristwatch.

In some embodiments, the systems, devices, and/or components (e.g., integrated circuits or integrated circuit packages) described herein may be integrated into an HMD. For example, such an HMD may include one or more light emitters and/or one or more light sensors incorporated into a portion of a frame of the HMD such that light can be emitted toward a tissue of a wearer of the HMD that is proximate to or touching the portion of the frame of the HMD. Example locations of such a portion of a frame of an HMD may include a portion configured to be proximate to an ear of the wearer (e.g., proximate to a superior tragus, proximate to a superior auricular, proximate to a posterior auricular, proximate to an inferior auricular, or the like), proximate to a forehead of the wearer, or the like. It should be noted that multiple sets of light emitters and light sensors may be incorporated into a frame of an HMD such that PPG can be determined from measurements associated with multiple body locations of a wearer of the HMD.

In the present description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

Embodiments disclosed herein may be used to implement components of an artificial reality system or may be implemented in conjunction with an artificial reality system. Artificial reality is a form of reality that has been adjusted in some manner before presentation to a user, which may include, for example, a virtual reality, an augmented reality, a mixed reality, a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including an HMD connected to a host computer system, a standalone HMD, a mobile device or computing system, or any other hardware platform capable of providing artificial reality content to one or more viewers.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments may be described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof. When implemented in software, firmware, middleware, or microcode, the program code or code segments to perform the associated tasks may be stored in a computer-readable medium such as a storage medium. Processors may perform the associated tasks.

It will be apparent to those skilled in the art that substantial variations may be made in accordance with specific requirements. For example, customized or special-purpose hardware might also be used, and/or particular elements might be implemented in hardware, software (including portable software, such as applets, etc.), or both. Further, connection to other computing devices such as network input/output devices may be employed.

With reference to the appended figures, components that can include memory can include non-transitory machine-readable media. The term “machine-readable medium” and “computer-readable medium” may refer to any storage medium that participates in providing data that causes a machine to operate in a specific fashion. In embodiments provided hereinabove, various machine-readable media might be involved in providing instructions/code to processing units and/or other device(s) for execution. Additionally or alternatively, the machine-readable media might be used to store and/or carry such instructions/code. In many implementations, a computer-readable medium is a physical and/or tangible storage medium. Such a medium may take many forms, including, but not limited to, non-volatile media, volatile media, and transmission media. Common forms of computer-readable media include, for example, magnetic and/or optical media such as compact disk (CD) or digital versatile disk (DVD), punch cards, paper tape, any other physical medium with patterns of holes, a RAM, a programmable read-only memory (PROM), an erasable programmable read-only memory (EPROM), a FLASH-EPROM, any other memory chip or cartridge, a carrier wave as described hereinafter, or any other medium from which a computer can read instructions and/or code. A computer program product may include code and/or machine-executable instructions that may represent a procedure, a function, a subprogram, a program, a routine, an application (App), a subroutine, a module, a software package, a class, or any combination of instructions, data structures, or program statements.

Those of skill in the art will appreciate that information and signals used to communicate the messages described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, AB, AC, BC, AA, ABC, AAB, AABBCCC, etc.

Further, while certain embodiments have been described using a particular combination of hardware and software, it should be recognized that other combinations of hardware and software are also possible. Certain embodiments may be implemented only in hardware, or only in software, or using combinations thereof. In one example, software may be implemented with a computer program product containing computer program code or instructions executable by one or more processors for performing any or all of the steps, operations, or processes described in this disclosure, where the computer program may be stored on a non-transitory computer readable medium. The various processes described herein can be implemented on the same processor or different processors in any combination.

Where devices, systems, components or modules are described as being configured to perform certain operations or functions, such configuration can be accomplished, for example, by designing electronic circuits to perform the operation, by programming programmable electronic circuits (such as microprocessors) to perform the operation such as by executing computer instructions or code, or processors or cores programmed to execute code or instructions stored on a non-transitory memory medium, or any combination thereof. Processes can communicate using a variety of techniques, including, but not limited to, conventional techniques for inter-process communications, and different pairs of processes may use different techniques, or the same pair of processes may use different techniques at different times.

The specification and drawings are, accordingly, to be regarded in an illustrative rather than a restrictive sense. It will, however, be evident that additions, subtractions, deletions, and other modifications and changes may be made thereunto. Thus, although specific embodiments have been described, these are not intended to be limiting. Various modifications and equivalents are within the scope of the following claims.

1. A system, comprising:
a reference signal generator configured to output one or more reference signals, wherein each reference signal includes a reference marker followed by a sequence of alignment pulses;
a first sensor configured to capture a first set of measurement samples at regular intervals corresponding to a first sampling period, wherein the first set of measurement samples includes direct or indirect measurements of a first reference signal in the one or more reference signals;
a second sensor configured to capture a second set of measurement samples at regular intervals corresponding to a second sampling period, wherein the second set of measurement samples includes direct or indirect measurements of the first reference signal or a different reference signal in the one or more reference signals; and
one or more processing units configured to time-align the first set of measurement samples to the second set of measurement samples through:
assigning a first timestamp to a first alignment pulse represented in the first set of measurement samples, wherein the first timestamp is relative to a first reference marker represented in the first set of measurement samples, and
assigning a second timestamp to a second alignment pulse represented in the second set of measurement samples, wherein the second timestamp is relative to the first reference marker as represented in the second set of measurement samples,
wherein for each reference signal, alignment pulses in the sequence of alignment pulses have a same pulse width and repeat according to a pulse period, and
wherein the first sensor and the second sensor are unsynchronized.

2. The system of claim 1, wherein the first reference marker includes one or more pulses, and wherein a duration of the first reference marker is at least two times longer than the first sampling period and the second sampling period.

3. The system of claim 1, wherein the first alignment pulse and the second alignment pulse are different alignment pulses in a same sequence of alignment pulses.

4. (canceled)

5. The system of claim 4, wherein the pulse period is longer than twice the first sampling period, the second sampling period, or both sampling periods.

6. The system of claim 4, wherein the pulse period is not an integer multiple of the first sampling period, the second sampling period, or both sampling periods.

7. The system of claim 4, wherein the pulse width is shorter than the first sampling period, the second sampling period, or both sampling periods.

8. The system of claim 1, wherein the first set of measurement samples includes a sample representing a signal that is not a reference signal, and wherein the one or more processing units are configured to assign a timestamp to the sample representing the signal that is not a reference signal, based on the first timestamp and the first sampling period.

9. The system of claim 1, wherein the first set of measurement samples and the second set of measurement samples represent concurrent measurements of the first reference signal.

10. An apparatus comprising:
a communications interface configured to receive a first set of measurement samples and a second set of measurement samples, wherein:
the first set of measurement samples was captured by a first sensor at regular intervals corresponding to a first sampling period and includes direct or indirect measurements of a first reference signal,
the second set of measurement samples was captured by a second sensor at regular intervals corresponding to a second sampling period and includes direct or indirect measurements of the first reference signal or a different reference signal, and
each reference signal includes a reference marker followed by a sequence of alignment pulses; and
one or more processing units configured to time-align the first set of measurement samples to the second set of measurement samples through:
assigning a first timestamp to a first alignment pulse represented in the first set of measurement samples, wherein the first timestamp is relative to a first reference marker represented in the first set of measurement samples, and
assigning a second timestamp to a second alignment pulse represented in the second set of measurement samples, wherein the second timestamp is relative to the first reference marker as represented in the second set of measurement samples,
wherein for each reference signal, alignment pulses in the sequence of alignment pulses have a same pulse width and repeat according to a pulse period, and
wherein the first sensor and the second sensor are unsynchronized.

11. The apparatus of claim 10, wherein the first reference marker includes one or more pulses, and wherein a duration of the first reference marker is at least two times longer than the first sampling period and the second sampling period.

12. The apparatus of claim 10, wherein the first alignment pulse and the second alignment pulse are different alignment pulses in a same sequence of alignment pulses.

13. (canceled)

14. The apparatus of claim 13, wherein the pulse period is longer than twice the first sampling period, the second sampling period, or both sampling periods.

15. The apparatus of claim 13, wherein the pulse period is not an integer multiple of the first sampling period, the second sampling period, or both sampling periods.

16. The apparatus of claim 13, wherein the pulse width is shorter than the first sampling period, the second sampling period, or both sampling periods.

17. The apparatus of claim 10, wherein the first set of measurement samples includes a sample representing a signal that is not a reference signal, and wherein the one or more processing units are configured to assign a timestamp to the sample representing the signal that is not a reference signal, based on the first timestamp and the first sampling period.

18. A method, comprising:
receiving, by a computing device comprising one or more processing units, a first set of measurement samples and a second set of measurement samples, wherein:
the first set of measurement samples was captured by a first sensor at regular intervals corresponding to a first sampling period and includes direct or indirect measurements of a first reference signal,
the second set of measurement samples was captured by a second sensor at regular intervals corresponding to a second sampling period and includes direct or indirect measurements of the first reference signal or a different reference signal, and
each reference signal includes a reference marker followed by a sequence of alignment pulses; and
time-aligning, by the one or more processing units, the first set of measurement samples to the second set of measurement samples, wherein the time-aligning comprises:
assigning a first timestamp to a first alignment pulse represented in the first set of measurement samples, wherein the first timestamp is relative to a first reference marker represented in the first set of measurement samples, and
assigning a second timestamp to a second alignment pulse represented in the second set of measurement samples, wherein the second timestamp is relative to the first reference marker as represented in the second set of measurement samples,
wherein for each reference signal, alignment pulses in the sequence of alignment pulses have a same pulse width and repeat according to a pulse period, and
wherein the first sensor and the second sensor are unsynchronized.

19. (canceled)

20. The method of claim 19, wherein:
the pulse period is longer than twice the first sampling period, the second sampling period, or both sampling periods; and
the pulse width is shorter than the first sampling period, the second sampling period, or both sampling periods.
